(19) United States
(12) Patent Application Publication
(10) Pub. No.: US 2025/0030971 A1
(43) Pub. Date: Jan. 23, 2025

(54) Earbud with Low Enoise

(71) Applicant: Google LLC, Mountain View, CA (US)

(72) Inventors: Mingfeng Xue, Mountain View, CA (US); Shengyin Ding, Cupertino, CA (US)

(73) Assignee: Google LLC, Mountain View, CA (US)

(21) Appl. No.: 18/909,297

(22) Filed: Oct. 8, 2024

Related U.S. Application Data
(60) Provisional application No. 63/674,019, filed on Jul. 22, 2024.

(51) Int. Cl. H04R 1/10; H05K 1/02

(52) U.S. Cl. CPC H04R 1/1041; H04R 1/1016; H04R 1/1025; H04R 1/1075; H05K 1/0277; H05K 2201/052; H05K 2201/09227; H05K 2201/10037; H05K 2201/10083; H05K 2201/10151

(57) ABSTRACT

Techniques and apparatuses are described for an earbud with low enoise. An electronic device includes: a flexible printed circuit (FPC) having first, second, and third regions, the FPC being shaped to form multiple layers including first, second, and third layers, the second region forming the second layer and being between the first layer formed by the first region and the third layer formed by the third region. The electronic device further includes a multi-layer board (MLB) in the first region. A battery connected to the FPC in the first region and disposed between the first and second regions. A speaker connected to the FPC in the second region and disposed between the second and third regions. Charger pins connected to the FPC in the third region. A microphone connected to the FPC in the third region. An infrared sensor connected to the FPC in the third region.

### CROSS-REFERENCE TO RELATED APPLICATION(S)

This application claims the benefit of U.S. Provisional Patent Application Ser. No. 63/674,019, filed on Jul. 22, 2024, the disclosure of which is incorporated by reference herein in its entirety.

### SUMMARY

Techniques and apparatuses are described that implement an earbud with low enoise. The present technology may employ architectures to compensate for electromagnetic (EM) coupling inside an earbud between a battery, a speaker, a main logic board, or a flexible printed circuit (FPC). Different architectures of the exterior of the earbud can lead to different interior spaces that are available for the FPC and impose limitations on the routing paths of the FPC. Techniques described herein are for an electronic device such as an earbud with an FPC having three regions that are formed in layers where components of the earbud along a voltage battery loop, such as a battery, battery pads, and a battery protection circuit are placed in the first region. The voltage battery loop can have a dedicated ground return. A middle disk area, or second region, of the earbud can have a large ground coverage area separate from the dedicated ground return for the voltage battery loop. A power trace can be located around a perimeter of the large ground coverage area in the second region to avoid magnetic field interference with a speaker located in the second region. A third region can include charger pins, a microphone, and an infrared sensor. Thus an earbud implemented with the described techniques, including the overall size of the FPC, can be smaller than previous implementations while providing grounding for a speaker yoke and having a low enoise for the earbud with minimized FPC-to-speaker coupling.

In aspects, an electronic device is disclosed that includes: a flexible printed circuit (FPC) having first, second, and third regions, the FPC being shaped to form multiple layers including first, second, and third layers, the second region forming the second layer and being between the first layer formed by the first region and the third layer formed by the third region. The electronic device further includes a multi-layer board (MLB) connected to the FPC in the first region. The electronic device further includes a battery connected to the FPC in the first region and disposed between the first and second regions. The electronic device further includes a speaker connected to the FPC in the second region and disposed between the second and third regions. The electronic device further includes charger pins connected to the FPC in the third region. The electronic device further includes a microphone connected to the FPC in the third region. The electronic device further includes an infrared sensor connected to the FPC in the third region.

In aspects, an earbud is disclosed that includes: a flexible printed circuit (FPC) having first, second, and third regions, the second region being between the first and third regions, the FPC having connectors configured to couple to components along a battery-voltage (VBAT) loop in the first region, the FPC having the VBAT loop routed within the first region, and the VBAT loop having a dedicated ground return. The earbud further includes a battery connected to the FPC in the first region and disposed between the first and second regions. The earbud further includes a speaker connected to the FPC in the second region and disposed between the second and third regions.

In aspects, an electronic device is disclosed that includes: a battery, a speaker, and a flexible printed circuit (FPC) connecting the battery and the speaker. The FPC has a middle disk area disposed between the battery and the speaker and having a ground coverage greater than a threshold. The electronic device further includes power and signal traces on the FPC that do not overlap with a speaker yoke area of the speaker. The power and signal traces are routed to produce a first H-field emission that substantially cancels a second H-field emission generated by the battery.

This Summary is provided to introduce simplified concepts systems and is directed at electronic devices, including earbuds, for low enoise, the concepts of which are further described below in the Detailed Description and Drawings. This Summary is not intended to identify essential features of the claimed subject matter, nor is it intended for use in determining the scope of the claimed subject matter.

### BRIEF DESCRIPTION OF DRAWINGS

Apparatuses and techniques for an earbud with low enoise are described with reference to the following drawings. The same numbers are used throughout the drawings to reference like features and components:

FIG. 1 illustrates an example device diagram of an electronic device in accordance with the described implementations;

FIG. 2A illustrates an example three dimensional diagram of components of the electronic device in which an earbud with low enoise can be implemented;

FIG. 2B illustrates an example cross section diagram of the electronic device in which an earbud with low enoise can be implemented;

FIG. 3A illustrates a diagram of a top layer of the FPC in which an earbud with low enoise can be implemented;

FIG. 3B illustrates a diagram of the FPC with grounding traces in which an earbud with low enoise can be implemented;

FIG. 3C illustrates a diagram of an enlarged view of a second region of the FPC in which an earbud with low enoise can be implemented; and

FIGS. 4 and 5 are graphs of enoise measurements compared between left and right earbuds with low enoise as described herein and conventional left and right earbuds.

### DETAILED DESCRIPTION

Systems and techniques directed at electronic devices, including earbuds, for low enoise are disclosed. Electronic devices such as earbuds have a formfactor that can shape or limit the space available in the earbud for components such as a flexible printed circuit (FPC), a battery, a battery-voltage (VBAT) loop, power traces, a speaker, a speaker yoke, etc. As the interior space of the earbud becomes limited, placement of the speaker or speaker yoke in proximity to the battery, the VBAT loop, the power traces, or other components can cause feedback, interference, and enoise in the speaker, which can produce poor quality tonal noise that is audible to a user of the earbud. For example, in some conventional earbuds, power traces in the earbud can carry alternating current (AC) ripples. When the power trace is coupled to a speaker coil for the speaker, the AC ripples then cause poor quality tonal noise in the speaker. To address such challenges, techniques are described that implement an earbud with low-enoise.

In example aspects, an electronic device (e.g., earbud) includes an architecture that compensates for EM coupling inside the device to reduce enoise. For example, the earbud includes an FPC having three regions formed in layers (e.g., the FPC is folded back and forth to form the layers). The FPC includes a VBAT loop routed only in the first region and having a dedicated ground return. The second, or middle region, is a disk area having a large ground coverage area separate from the dedicated ground return of the VBAT loop. In aspects, a power trace is routed proximate to a perimeter of the disk area to avoid magnetic field interference with a speaker located between the first region and the second region. Other components such as charger pins to charge the battery that is coupled to the first region, a microphone, and/or an infrared sensor are coupled to the third region. In such an implementation, the second region is disposed directly between the battery and the speaker.

The following discussion describes operating environments, techniques that may be employed in the operating environments, and example methods. Although techniques for an earbud with low enoise are described, it is to be understood that the subject of the appended claims is not necessarily limited to the specific features or methods described. Rather, the specific features and methods are disclosed as example implementations and reference is made to the operating environment by way of example only.

### Example Environment

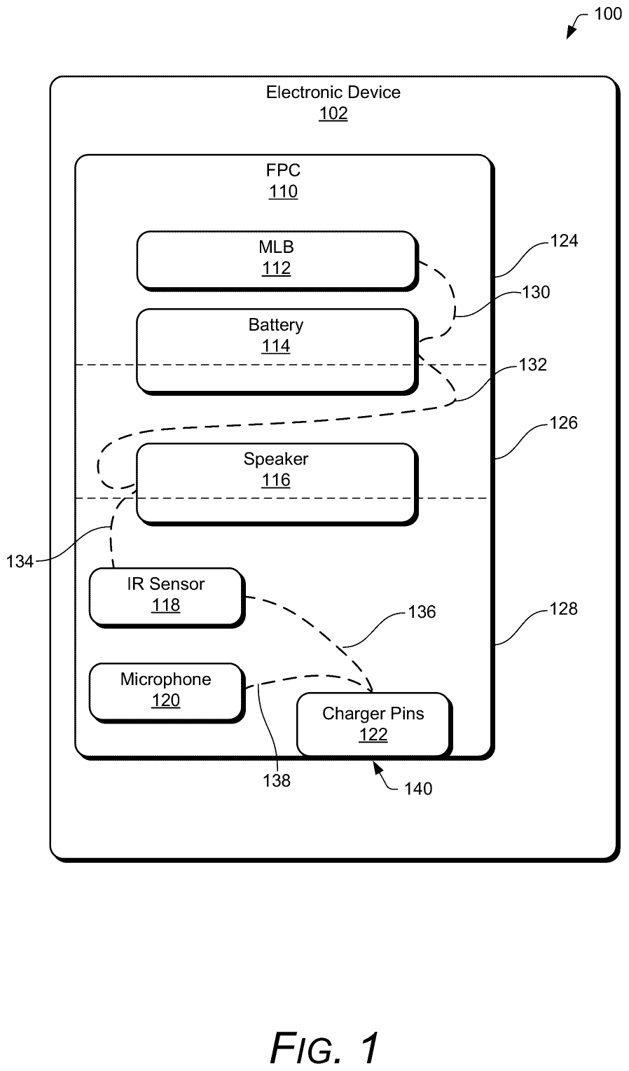

FIG. 1 illustrates an example device diagram 100 of an electronic device 102, such as an earbud, with a flexible printed circuit (FPC) 110 in accordance with the described implementations. The electronic device 102 may include additional components and interfaces omitted from FIG. 1 for the sake of clarity.

The electronic device 102 includes a multi-layer board (MLB) 112, a battery 114, a speaker 116, an infrared (IR) sensor 118, a microphone 120, and charger pins 122. The electronic device 102 can perform tasks such as outputting audible sounds via the speaker 116, detecting proximity of a user to activate the electronic device 102, receiving voice input via the microphone, and so on. Components of the electronic device can communicate wirelessly with a second electronic device (not pictured). The second electronic device can be any suitable computing device including a smartphone, a computing device, a laptop, a tablet, a handheld electronic device, etc. The second electronic device may communicate wirelessly with the electronic device 102 via a wireless protocol such as Bluetooth™ or Wi-Fi. The electronic device 102 may be used in conjunction with the second electronic device to output audible sounds generated and transmitted by the second electronic device. For example, the second electronic device may transmit digital music to the electronic device 102 for playback via the speaker 116. It should be appreciated that the electronic device 102 may be employed with a second electronic device to play any sound including an audio track that corresponds to a video, audio for a telephone call, and so on. Additionally, microphone 120 can receive sounds, such as voice input from the user, and transmit the sounds to the second electronic device.

The electronic device 102 may be one of two earbuds that work in conjunction with one another. Each of the two earbuds may be shaped in mirror images of one another. The mirror-imaged shape can be to fit in a left ear and a right ear of a user, respectively. An earbud may be wireless and powered via the battery 114. The battery 114 may be charged or recharged via a charging case that is connected to the earbud via charger pins 122. The charging case may be capable of charging two earbuds simultaneously.

The FPC 110 can be a flexible printed circuit board, which can be a flexible electronic assembly that can be formed in various shapes. The FPC 110 can be used for assembling electronic circuits by mounting electronic components on flexible plastic substrates. Flexible electronic assemblies may be manufactured using identical components used for rigid printed circuit boards, allowing the board to conform to a desired shape, or to flex during its use. The FPC 110 can be used to form electronic circuits for the electronic device 102. The FPC 110 can include multiple regions including first region 124, second region 126, and third region 128 connected together in series (e.g., the first region 124 is connected to the second region 126, which is connected to the third region). The first region 124 can be connected to the MLB 112, which is a main logic board for controlling the electronic device 102. The battery 114 can be a rechargeable battery such as a lithium-ion battery or other type of battery and can be connected to the FPC 110 in the first region 124. The battery 114 can be disposed within a housing of the electronic device 102 between the first region 124 and the second region 126 of the FPC 110. The MLB 112 can be electrically coupled to the battery 114 via trace 130. The speaker 116 can be connected to the FPC 110 in second region 126 and can be disposed between the second region 126 and the third region 128. The battery 114 can be electrically connected to the speaker 116 via trace 132. The IR sensor 118, the microphone 120, and the charger pins 122 can be connected to the FPC 110 in the third region 128. The IR sensor 118 can be electrically connected to the speaker 116 via trace 134. The IR sensor 118 can be electrically connected to the charger pins 122 via trace 136. The microphone 120 can be electrically connected to the charger pins 122 via trace 138.

The charger pins 122 can be employed to electrically connect the electronic device 102 to a charging case. In one aspect, the charger pins 122 are located at a bottom surface 140 of the third region 128 of the FPC 110. The bottom surface 140 can face in a direction away from a direction in which the speaker 116 is located in relative to the charger pins 122. It should be appreciated that the charger pins 122 can be located on any surface of the FPC 110.

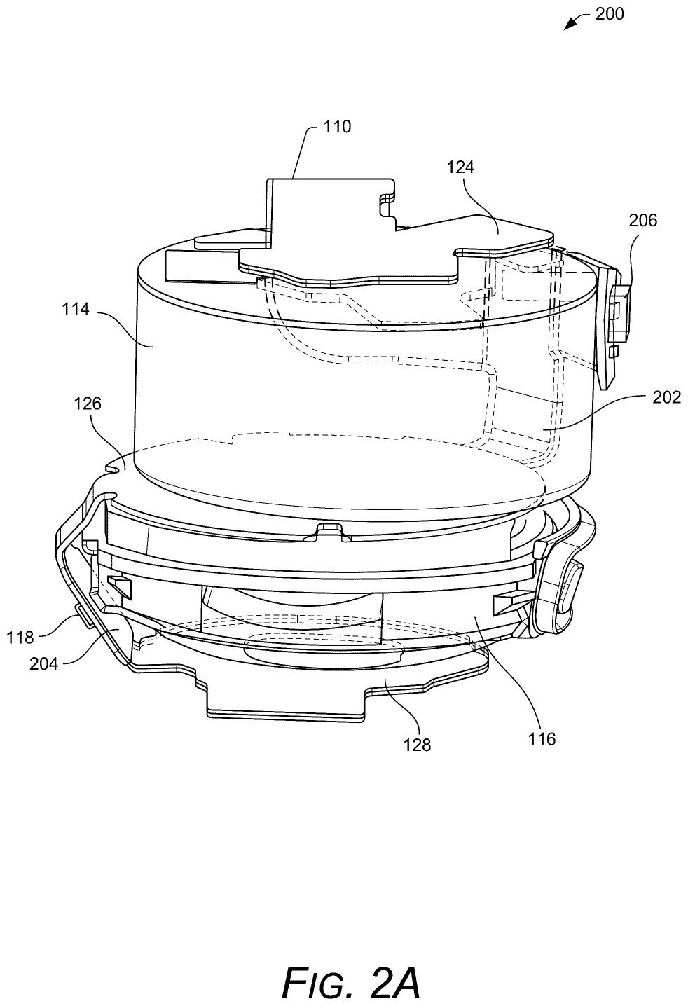

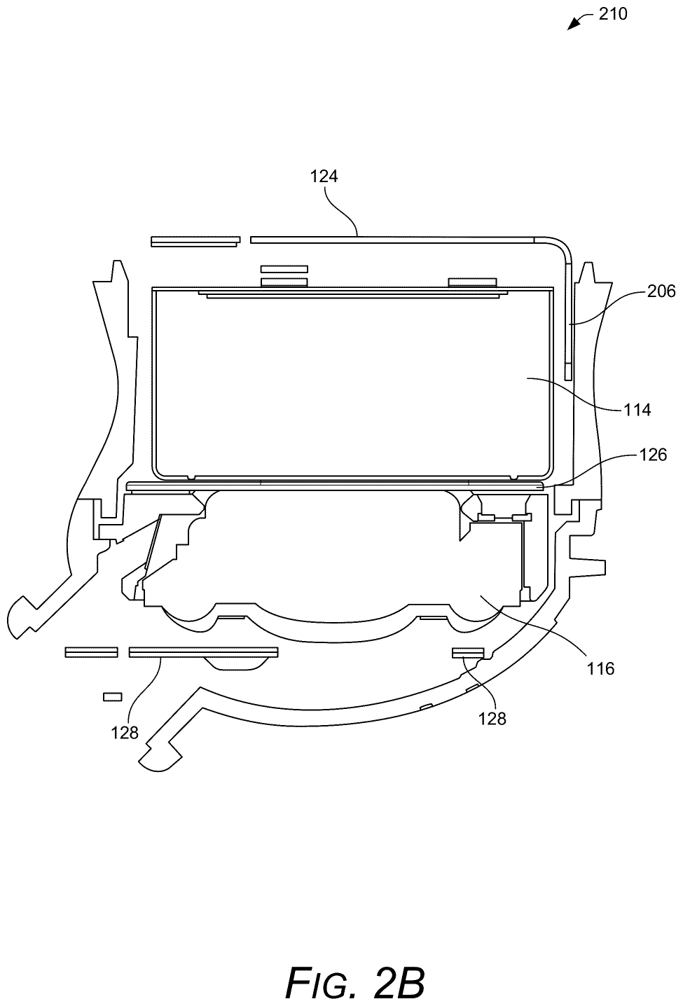

FIG. 2A illustrates an example three dimensional diagram 200 of an electronics assembly of the electronic device 102 of FIG. 1. The FPC 110 is depicted with the battery 114 disposed between first region 124 and second region 126 of the FPC 110. The speaker 116 is depicted as being disposed between the second region 126 and the third region 128 of the FPC 110. The diagram 200 of the electronics assembly depicts that the FPC 110 is shaped to form multiple layers. For example, the first region 124 forms a first layer, the second region 126 forms a second layer, and the third region 128 forms a third layer. Accordingly, the FPC 110 is bent to for a substantial “S” shape. The first, second, and third layers are depicted as each forming a plane where each layer is parallel or substantially parallel to one another. It should be appreciated that the first, second, and third layers may or may not be parallel to one another but can be formed at any angle. In one aspect, the second layer formed by the second region 126 is formed between the first layer and the third layer.

It should be appreciated that the FPC 110 with the first region 124, the second region 126, and the third region 128 can be formed as one unit or one shape such that the first region 124 can be connected to the second region 126 via a bend region 202 and the second region 126 can be connected to the third region 128 via a bend region 204. In some aspects, the IR sensor 118 is located on the bend region 204. The bend region 202 is depicted as located behind the battery 114 in FIG. 2A. The electronic device 102 can also include a power protection circuit 206.

FIG. 2B illustrates an example cross section diagram 210 of the electronics assembly of FIG. 2A. The FPC 110 is also depicted in diagram 210 with the battery 114 disposed between first region 124 and second region 126 of the FPC 110. The speaker 116 is also depicted as disposed between the second region 126 and the third region 128 of the FPC 110. Diagram 210 also depicts the first region 124, the second region 126, and the third region 128 as forming three layers that are substantially parallel to one another. In the electronics assembly, the second region 126 is located directly between the battery 114 and the speaker 116.

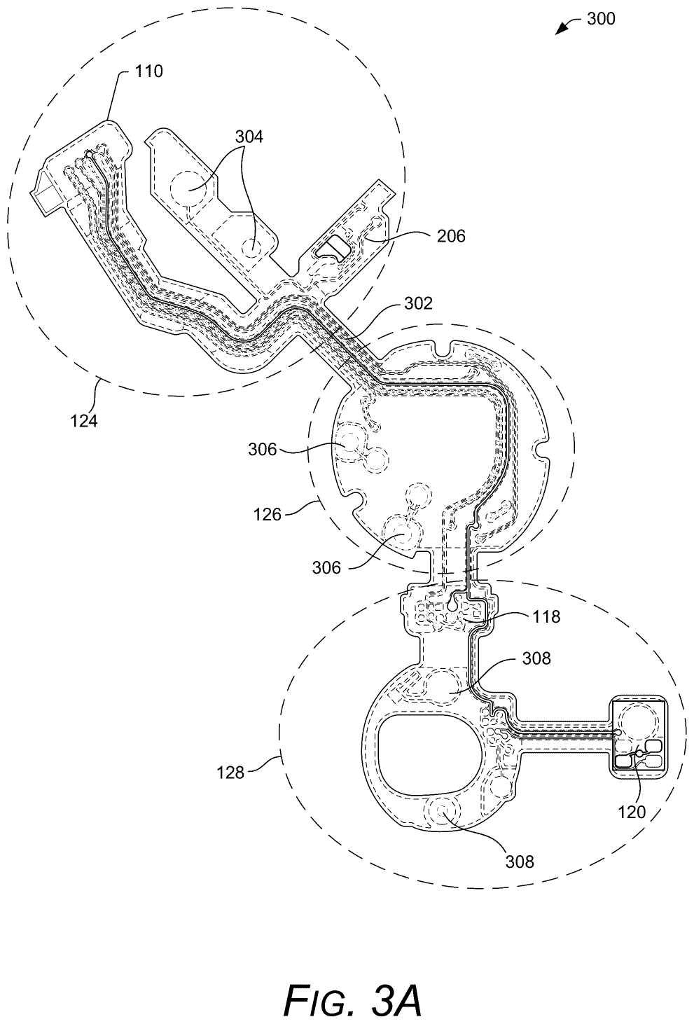

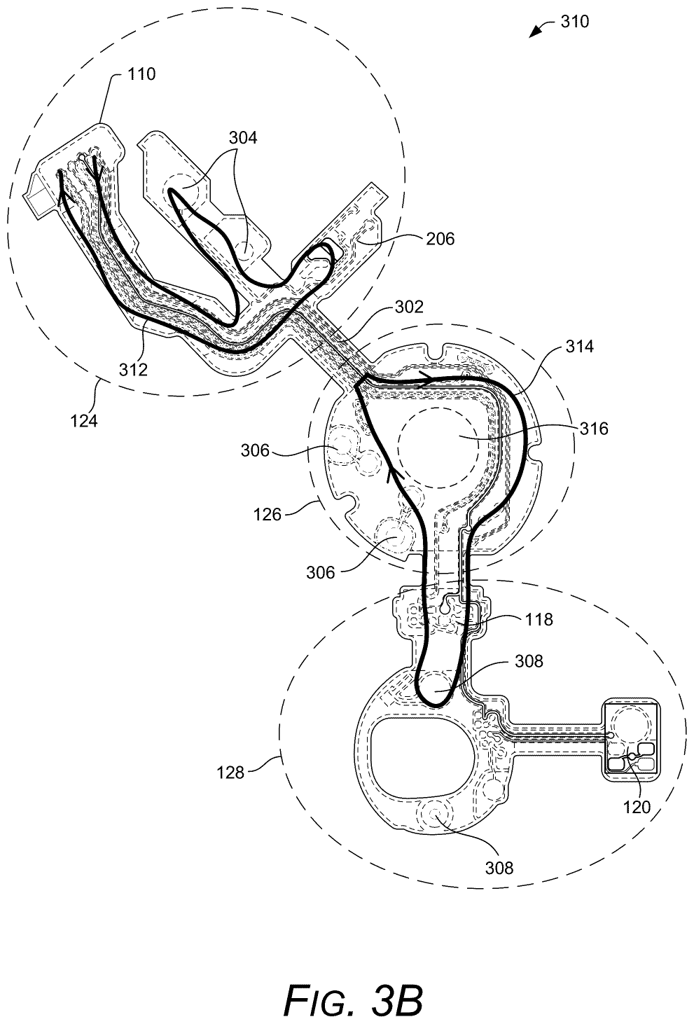

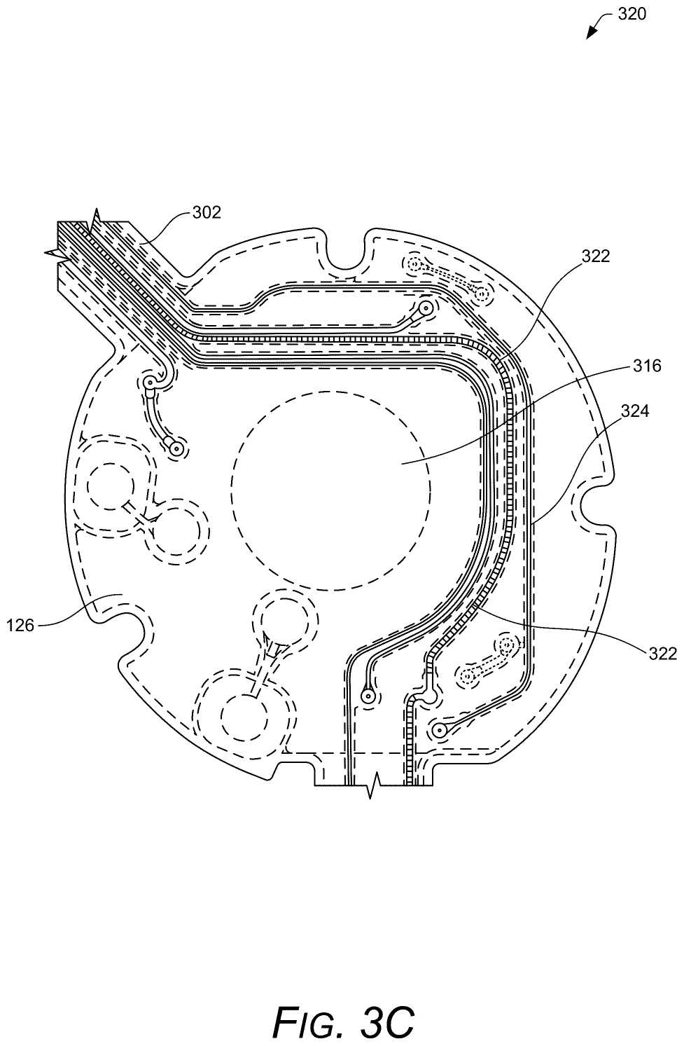

FIG. 3A illustrates a diagram 300 of a top layer of the FPC 110 of FIGS. 1, 2A, and 2B. The FPC 110 is depicted in an unfolded or unbent shape with the first region 124, the second region 126, and the third region 128 each laid out in the same plane. This configuration or unfolded state may be the state in which FPC 110 is manufactured but not necessarily the state in which the FPC 110 is formed into after installation in the electronic device such as the electronic device 102 of FIG. 1.

Diagram 300 depicts traces 302, which can be power traces, signal traces, or ground traces that electrically connect the components connected to the FPC 110. In previous solutions, the routing of power and grounding through the FPC has caused enoise and bad tonal audio quality. The routing of the FPC 110 described herein, however, produces significantly reduced enoise compared to the previous solutions.

Diagram 300 also depicts battery pads 304, speaker pads 306, and charging pads 308. The battery pads electrically connect the battery 114 to the FPC 110. The speaker pads 306 electrically connect the speaker 116 to the FPC 110. The charging pads 308 electrically connect the charger pins 122 to the FPC 110.

FIG. 3B illustrates a diagram 310, which is a view of diagram 300 of FIG. 3A with grounding traces depicted. Diagram 310 depicts a grounding trace 312 which is a dedicated ground trace in the first region 124. The grounding trace 312 electrically grounds the battery voltage (VBAT) loop and the components of the VBAT loop, including the battery pads 304 and a power protection circuit 206, also referred to as a battery protection circuit. The grounding trace 312 can also ground the battery 114. Ground trace 314 can be referred to as a second ground trace and can be located between the battery 114 and the speaker 116 once the electronic device 102 has been assembled. The ground trace 314 can electrically ground the speaker pads 306 and the charging pads 308. The use of grounding trace 312 and the grounding trace 314 ensures that the battery 114 is separately grounded from the speaker 116 to reduce or lower potential enoise or other bad tonal audio as compared to an electronic device that does not have separate grounding traces for the battery and speaker. Grounding trace 314 is depicted as being routed around a middle disk area 316 (e.g., central area) in the second region 126. In one aspect, grounding trace 314 does not cross the middle disk area 316 of second region 126. In an implementation, the middle disk area 316 is aligned with the speaker yoke area of the speaker 116 when assembled together in the electronics assembly. Accordingly, the grounding trace 314 is routed around and does not cross or overlap an area of the second region that corresponds to, or is aligned with, the speaker yoke area of the speaker 116.

FIG. 3C illustrates a diagram 320, which is an enlarged view of the second region 126 of the FPC 110. The enlarged view of the second region 126 of the FPC 110 serves to depict a route of a power trace 322. The power trace 322 can provide power to the microphone 120 and the IR sensor 118 of FIG. 1, which can be located in the third region 128 of the FPC 110. In one aspect, the power trace 322 carries 1.8 volts (V) of current. The power trace 322 is depicted as being routed around or proximate to a perimeter of the second region 126. In one aspect, the power trace 322 does not cross the middle disk area 316 of the second region 126. In one example, a signal routing for a signal trace 324 can also be routed around or proximate to a perimeter of the second region 126 and not through the middle disk area 316. Such a routing of the power trace 322 and the signal trace 324 around the perimeter of the second region 126 can result in an optimization for H-field emission (e.g., cancellation with battery H-field emission). In one example, the middle disk area 316 provides ground coverage. The ground coverage associated with the middle disk area 316 can be greater than a threshold. The threshold can be a value set for an area measured on the second region 126. In one aspect, routing of the power trace 322 and the signal trace 324 around the perimeter of the second region 126 can avoid overlap with a speaker yoke area for the speaker 116.

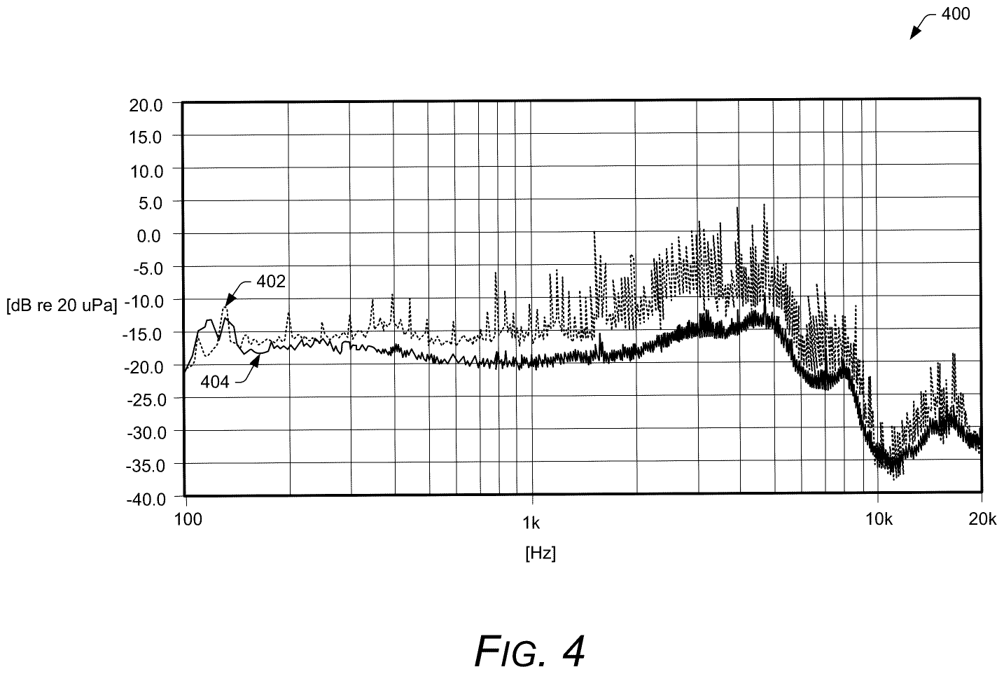

FIG. 4 is a graph 400 of enoise measurements compared between a left earbud with low enoise as described herein and a conventional left earbud. The graph 400 is of a left side earbud. Line 402 shows enoise results of a conventional left earbud and line 404 depicts enoise results of a left earbud using the techniques depicted and described herein. Graph 400 depicts measures of decibels (dB) (e.g., dB re 20 uPa, which represents a sound pressure level on the dB scale, where 20 uPa (0.0 dB) is the reference level) as an output of frequency in Hertz (Hz). Graph 400 depicts a reduction in enoise with embodiments depicted and described herein. As shown in graph 400, the enoise of the conventional left earbud represented by line 402 crosses the human hearing threshold of 0.0 dB between 2 k Hz and 5 k Hz, which is tonal noise to a user of the earbud. The enoise of the left earbud using the techniques described herein and represented by line 404 remains below the human hearing threshold and therefore does not produce tonal noise for the user.

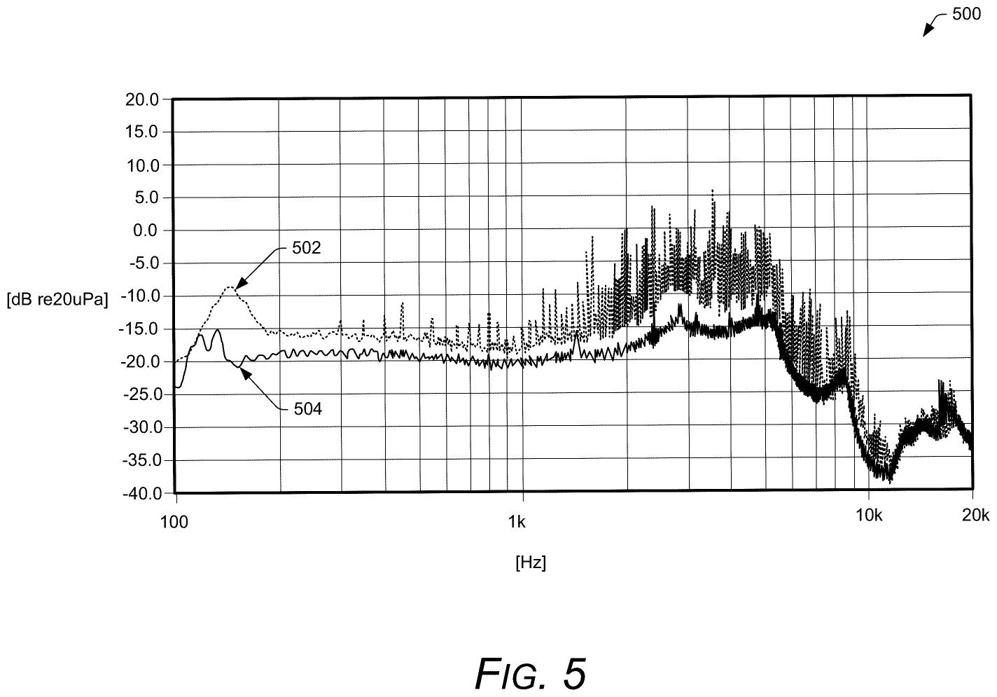

FIG. 5 is a graph 500 of enoise measurements compared between a right earbud with low enoise as described herein and a conventional right earbud. The graph 500 is of a right-side earbud. Line 502 shows enoise results of a conventional right earbud and line 504 depicts enoise results of a right earbud using the techniques depicted and described herein. Graph 500 depicts measures of dB, specifically dB re 20 uPa, as an output of frequency in Hz. Graph 500 depicts a reduction in enoise with embodiments depicted and described herein. Note that, similar to FIG. 4, in FIG. 5 the enoise of the conventional right earbud represented by line 502 crosses the human hearing threshold of 0.0 dB between 2 k Hz and 5 k Hz, which is tonal noise to a user of the earbud. The enoise of the right earbud using the techniques described herein and represented by line 504 remains below the human hearing threshold and therefore does not produce tonal noise for the user.

### CONCLUSION

Although techniques using, and apparatuses including, an earbud with low enoise have been described in language specific to features and/or methods, it is to be understood that the subject of the appended claims is not necessarily limited to the specific features or methods described. Rather, the specific features and methods are disclosed as example implementations of an earbud with low enoise.

What is claimed is:

1. An electronic device comprising:
a flexible printed circuit (FPC) having first, second, and third regions, the FPC being shaped to form multiple layers including first, second, and third layers, the second region forming the second layer and being between the first layer formed by the first region and the third layer formed by the third region;
a main logic board connected to the FPC in the first region;
a battery connected to the FPC in the first region and disposed between the first and second regions;
a speaker connected to the FPC in the second region and disposed between the second and third regions;
charger pins connected to the FPC in the third region;
a microphone connected to the FPC in the third region; and
an infrared sensor connected to the FPC in the third region.

2. The electronic device of claim 1, further comprising:
a battery voltage loop and components of the battery voltage loop located in the first region, wherein the components of the battery voltage loop include battery pads and a battery protection circuit.

3. The electronic device of claim 2, further comprising:
a dedicated ground trace located in the first region for electrically grounding the battery and the battery voltage loop.

4. The electronic device of claim 3, further comprising:
a second ground trace located between the speaker and the battery.

5. The electronic device of claim 1, further comprising:
a power trace located around a perimeter of the second region, wherein the power trace does not overlap with a speaker yoke area for the speaker.

6. The electronic device of claim 1, further comprising:
a signal trace located around a perimeter of the second region.

7. The electronic device of claim 1, further comprising a power trace and a signal trace located in the second region, wherein the power trace and the signal trace are routed around a middle disk area of the second region to compensate for H-field emissions from the battery.

8. The electronic device of claim 1, wherein the charger pins are located at a bottom surface of the third region and wherein the bottom surface faces in a direction away from the speaker.

9. An earbud comprising:
a flexible printed circuit (FPC) having first, second, and third regions, the second region being between the first and third regions, the FPC having connectors configured to couple to components along a battery-voltage (VBAT) loop in the first region, the FPC having the VBAT loop routed within the first region, the VBAT loop having a dedicated ground return within the first region;
a battery connected to the FPC in the first region and disposed between the first and second regions; and
a speaker connected to the FPC in the second region and disposed between the second and third regions, the second region having a middle disk area aligned with a speaker yoke of the speaker, the second region having a power trace and a signal trace routed around the middle disk area.

10. An electronic device comprising:
a battery;
a speaker;
a flexible printed circuit (FPC) connecting the battery and the speaker, the FPC having a middle disk area disposed directly between the battery and the speaker, the middle disk area having a ground coverage greater than a threshold; and
power and signal traces on the FPC that do not overlap with a speaker yoke area of the speaker, the power and signal traces routed to produce a first H-field emission that substantially cancels a second H-field emission generated by the battery.
